(19) United States
(12) Patent Application Publication
(10) Pub. No.: US 2022/0033957 A1
(43) Pub. Date: Feb. 3, 2022

(54) ANTIMICROBIAL SHEET AND MANUFACTURING METHOD THEREOF

(71) Applicant: UACJ Corporation, Tokyo (JP)

(72) Inventors: Atsushi KOISHIKAWA, Aichi (JP); Kenji NOSE, Aichi (JP)

(21) Appl. No.: 17/277,420

(22) PCT Filed: Oct. 17, 2019
(86) PCT No.: PCT/JP2019/040795

§ 371 Date: Mar. 18, 2021

(30) Foreign Application Priority Data
Oct. 25, 2018 (JP) 2018-201040

(51) Int. Cl. C23C 14/20

(52) U.S. Cl. CPC C23C 14/20

(57) ABSTRACT

An antimicrobial sheet (1) includes 100-200 mg/m² of copper particles (3) adhered to a surface of a resin (polymer) film (2). The antimicrobial sheet has a total light transmittance at wavelengths of 380-780 nm of 20% or more. The copper particles have an average circle-equivalent diameter in the range of 10-30 nm. The antimicrobial sheet can be prepared by performing vacuum deposition to form the copper particles on the resin film under the condition that the pressure is controlled to within the range of 1×10⁻⁴-1×10⁻² Pa during the vacuum deposition.

### TECHNICAL FIELD

The present invention relates to an antimicrobial sheet and a manufacturing method thereof.

### BACKGROUND ART

In recent years, the use of electronic devices, such as personal computers, has been increasing in medical-treatment facilities, food-processing facilities, and the like. In medical-treatment facilities and the like, there is demand to curtail the indoor propagation of harmful microorganisms, such as pathogenic microbes, and to maintain indoor cleanliness. In the past, indoor cleanliness in these types of facilities has been maintained using various methods such as cleaning by wiping away with water, disinfecting using a pharmaceutical agent, etc. To maintain indoor cleanliness using a method such as cleaning and disinfection, it is necessary to periodically perform cleaning, disinfection, etc.

However, because interfaces, such as keyboards, operation panels, and touch panels, of electronic devices are frequently touched by numerous people, cleanliness tends to be impaired. To maintain the cleanliness of such parts, it is desirable to ideally perform cleaning, disinfection, etc. each time of use; however, it is extremely bothersome to perform cleaning, etc. each time of use. Consequently, there is demand to reduce the frequency of cleaning, disinfection, etc.

With respect to such a problem, a method has been receiving attention that reduces the frequency of cleaning, disinfection, etc. by covering the interface with a sheet, a film, or the like that has antimicrobial activity, i.e., that acts to curtail the propagation of microbes. For example, in Patent Document 1, an antimicrobial film is described in which at least one layer of an antimicrobial, metal thin film is formed on at least one surface of a flexible, high-molecular-weight, film base material, wherein the metal thin film is formed by a vacuum-depositing method, which is performed by heating a metal-evaporation source to melt it.

### PRIOR ART LITERATURE

### Patent Documents

Patent Document 1

Japanese Laid-open Patent Publication 2010-247450

### SUMMARY OF THE INVENTION

### Problem to be Solved by the Invention

In the antimicrobial film described in Patent Document 1, in order for the antimicrobial, metal thin film to sufficiently exhibit antimicrobial effects, it is necessary to increase the thickness of the antimicrobial, metal thin film to a certain extent. However, if the thickness of the antimicrobial, metal thin film becomes too large, then it becomes difficult for visible light to pass through the antimicrobial film. Consequently, in the situation in which the antimicrobial film described in Patent Document 1 is used on an interface, such as a keyboard, an operation panel, a touch panel, or the like, of an electronic device, there is a risk that it will lead to a decrease in the visibility of the interface.

The present invention was conceived considering this background and aims to provide an antimicrobial sheet having high transparency of visible light and strong antimicrobial effects.

### Means for Solving the Problems

One aspect of the present invention is an antimicrobial sheet that comprises:

a resin film; and

copper particles, which are adhered to at least one surface of the resin film;

wherein:

a total light transmittance at wavelengths of 380-780 nm is 20% or more;

an average circle-equivalent diameter of the copper particles is 10-30 nm; and

an adhered amount of the copper particles is 100-200 mg/μm².

### Effects of the Invention

The above-mentioned antimicrobial sheet comprises the resin film and the copper particles, which are formed on the resin film and have an average circle-equivalent diameter in the above-mentioned specific range. By setting the adhered amount of the copper particles to the above-mentioned specific range, an antimicrobial sheet, which exhibits strong antimicrobial effects against various microbes, can be obtained.

In addition, by forming the copper particles with an average circle-equivalent diameter in the above-mentioned specific range on the resin film, the visible-light transparency can be remarkably increased. As a result, a total light transmittance in the above-mentioned specific range can be achieved. An antimicrobial sheet having a total light transmittance in the above-mentioned specific range excels in visible-light transparency and can curtail a worsening in the visibility of an interface, such as a keyboard, an operation panel, or a touch panel, of an electronic device.

As described above, the above-mentioned antimicrobial sheet excels in antimicrobial effects and in visible-light transparency. Consequently, it can be suitably used for the protection of the interface of an electronic device.

### BRIEF DESCRIPTION OF THE DRAWINGS

FIG. 1 is a partial, enlarged, cross-sectional view of an antimicrobial sheet according to a working example.

FIG. 2 is an SEM image of Test Material A2.

FIG. 3 is an SEM image of Test Material A6.

FIG. 4 is an SEM image of Test Material A11.

FIG. 5 is an SEM image of Test Material A21.

FIG. 6 is a photograph, in lieu of a drawing, that shows the state in which Test Material A10 and printed matter have been overlaid.

FIG. 7 is a photograph, in lieu of a drawing, that shows the state in which Test Material A11 and printed matter have been overlaid.

FIG. 8 is a photograph, in lieu of a drawing, that shows the state in which Test Material A12 and printed matter have been overlaid.

FIG. 9 is a photograph, in lieu of a drawing, that shows the state in which Test Material A13 and printed matter have been overlaid.

### MODES FOR CARRYING OUT THE INVENTION

In the above-mentioned antimicrobial sheet, a resin film that is transparent to visible light can be used as the resin film. The resin film preferably contains one or two or more resins from among polyester, polyolefin, polycarbonate, polyurethane, polyvinyl chloride, and silicone. Because each of these resins has a high refractive index, the visible-light transparency of the antimicrobial sheet can be further increased. In addition, because each of these resins has high heat resistance, deterioration of the resin film when vacuum deposition is performed in the antimicrobial-sheet manufacturing process can be curtailed.

For example, polyethylene terephthalate, polymethylene terephthalate, polybutylene terephthalate, polyethylene naphthalate, polybutylene naphthalate, or the like can be used as the polyester. In addition, for example, a copolymer that contains an olefin—for example, a homopolymer of olefin, such as polyethylene and polypropylene; an ethylene-propylene copolymer; or the like—can be used as the polyolefin.

The thickness of the resin film can be set to, for example, 5-250 μm. In the situation in which the thickness of the resin film is less than 5 μm, handling of the resin film in the manufacturing process tends to become difficult. On the other hand, in the situation in which the thickness of the resin film is more than 250 μm, there is a risk that it will lead to a decrease in visible-light transparency.

Numerous copper particles are adhered to the resin film. The copper particles may be composed of pure copper or may be composed of a copper alloy. In the situation in which the copper particles are composed of a copper alloy, from the viewpoint of causing antimicrobial effects owing to the copper to be sufficiently exhibited, the copper content in the copper alloy is preferably 60 mass % or more.

The average circle-equivalent diameter of the copper particles is 10-30 nm. By setting the average circle-equivalent diameter of the copper particles to within the above-mentioned specific range, an antimicrobial sheet that excels in visible-light transparency can be obtained. In the situation in which the average circle-equivalent diameter of the copper particles is less than 10 nm, visible light tends to be scattered by the copper particles. In addition, in this situation, because the layer of the copper particles optically behaves as a continuous film, there is a risk that it will lead to a decrease in visible-light transparency.

In addition, in the situation in which the average circle-equivalent diameter of the copper particles is more than 30 nm, the copper particles will agglomerate, resulting in the state in which the layer of the copper particles is nearly a continuous film. Consequently, in this situation as well, there is a risk that it will lead to a decrease in visible-light transparency.

It is noted that the average circle-equivalent diameter of the copper particles is a value that is calculated by the method below. First, copper particles on the resin film are observed using an SEM (i.e., a scanning-electron microscope), and an SEM image of the copper particles is acquired. The observation magnification and the surface area of the visual field are not particularly limited, as long as the number of copper particles within the visual field can be made sufficiently large. For example, the observation magnification can be appropriately selected from within the range of 10,000-300,000 times. The circle-equivalent diameters of the copper particles present in the SEM image obtained using an image-analyzing apparatus is calculated. The arithmetic average of these circle-equivalent diameters should be taken as the average circle-equivalent diameter of the copper particles.

In addition, the adhered amount of copper particles is set to 100-200 mg/μm². Thereby, an antimicrobial sheet that excels both in antimicrobial effects and visible-light transparency can be obtained. In the situation in which the adhered amount of copper particles is less than 100 mg/μm², the amount of copper adhered to the resin film will be insufficient, and consequently there is a risk that it will lead to a decrease in the antimicrobial effects. In the situation in which the adhered amount of the copper particles is more than 200 mg/μm², the layer of the copper particles will become excessively thick, and therefore there is a risk that it will lead to a decrease in visible-light transparency.

The adhered amount of copper particles is calculated by, for example, measuring the characteristic X-ray intensity of the Cu using X-ray fluorescence analysis and then converting the characteristic X-ray intensity to an adhered amount using a previously prepared calibration curve.

The number of exposed copper particles on the surface of the antimicrobial film is preferably 1,500-5,000 particles/μm². In this situation, the visible-light transparency of the antimicrobial sheet can be further increased. The number of exposed copper particles on the surface of the antimicrobial film can be calculated by acquiring an SEM image of copper particles, the same as with the average circle-equivalent diameter described above, counting the number of copper particles present in the SEM image of the copper particles using an image-analyzing apparatus, and converting that number into the number per unit of area.

The total light transmittance of the above-mentioned antimicrobial sheet at wavelengths of 380-780 nm is 20% or more. Because an antimicrobial sheet having a total light transmittance in the above-mentioned specific range has high transparency of visible light, antimicrobial effects can be exhibited without impairing the visibility of an interface, such as a keyboard, of an electronic device. For this reason, the above-mentioned antimicrobial sheet is suitable for the protection of interfaces. It is noted that the total light transmittance of the antimicrobial sheet at wavelengths of 380-780 nm is a value that is measured by a method that conforms to JIS K7361-1:1997. For example, a haze meter can be used in the measurement of the total light transmittance.

The total light transmittance at wavelengths of 380-780 nm is preferably 30% or more, more preferably 40% or more, yet more preferably 45% or more, and in particular preferably 50% or more. In this situation, because the color of the antimicrobial sheet becomes lighter, a change in the color tone of the interface when it is covered by the antimicrobial sheet can be more effectively curtailed.

As described above, the antimicrobial sheet has strong antimicrobial effects and has excellent visible-light transparency. Consequently, for example, not only can it protect an interface that has a backlight, such as a touch panel, but can also protect even an interface that does not have a backlight, such as a keyboard, without impairing visibility. For this reason, the above-mentioned antimicrobial sheet is particularly suitable as a keyboard cover.

The above-mentioned antimicrobial sheet may have a primer layer between the resin film and the copper particles. In this situation, adhesiveness of the resin film to the copper particles is further improved, and thereby flaking of the copper particles off of the resin film can be curtailed over a longer term. As a result, the antimicrobial effects of the above-mentioned antimicrobial sheet can be maintained over a longer term.

For example, an adhesive agent having strong adhesiveness to both the resin film and the copper particles can be used as the primer layer. Examples of such an adhesive agent include adhesive agents containing a resin, such as a polyamide-based resin, a polyolefin-based resin, an epoxy-based resin, a polyester-based resin, a polyurethane-based resin, an acrylic-based resin, a nitrocellulose-based resin, or the like.

In addition, an adhesive layer for affixing the antimicrobial sheet to an object to be protected may be provided on a rear surface of the resin film of the antimicrobial sheet, that is, on the surface of the resin film on the side that does not have the copper particles. The material of the adhesive layer is not particularly limited, as long as it is transparent. For example, an acrylic-based adhesive, a rubber-based adhesive, a urethane-based adhesive, a silicone-based adhesive, or the like can be used as the adhesive layer.

In preparing the above-mentioned antimicrobial sheet, for example, a method can be used in which the above-mentioned resin film is prepared, after which the above-mentioned copper particles are formed on the above-mentioned resin film by performing vacuum deposition, wherein the pressure is controlled to within the range of 1×10⁻⁴-1×10⁻² Pa.

By setting the pressure during the vacuum deposition to within the above-mentioned specific range, the average circle-equivalent diameter of the copper particles formed on the resin film can be controlled to within the above-mentioned specific range. In the situation in which the pressure during the vacuum deposition becomes less than 1×10⁻⁴ Pa, a continuous film of copper tends to form on the resin film. In addition, in the situation in which the pressure during the vacuum deposition is more than 1×10⁻² Pa, the average circle-equivalent diameter of the copper particles tends to become large. Consequently, in the situation in which the pressure during the vacuum deposition deviates from the above-mentioned specific range, there is a risk that it will lead to a reduction in the visible-light transparency. From the viewpoint of reliably forming copper particles on the resin film, it is preferable to perform the vacuum deposition such that the pressure during the vacuum deposition is within the range of 1×10⁻³-1×10⁻² Pa.

The deposition rate during the vacuum deposition is preferably 0.5-5 nm/s. By setting the deposition rate to within the above-mentioned specific range, a worsening in productivity can be avoided while at the same time copper particles having an average circle-equivalent diameter in the above-mentioned specific range can be formed more reliably. In the situation in which the deposition rate is less than 0.5 nm/s, the time needed for the vacuum deposition becomes long, and therefore there is a risk that it will lead to a worsening in productivity. In addition, in the situation in which the deposition rate is more than 5 nm/s, a continuous film of copper readily forms on the resin film, and therefore there is a risk that it will lead to a reduction in visible-light transparency.

In the above-mentioned manufacturing method, after the resin film has been prepared and before vacuum deposition is performed, a pretreatment may be performed on the resin film as needed. For example, a treatment for normalizing the surfaces of the resin film can be performed as the pretreatment. Specifically, a surface treatment, such as a corona-discharge treatment, a plasma treatment, or a glow-discharge treatment, can be used as such a treatment.

### Working Examples

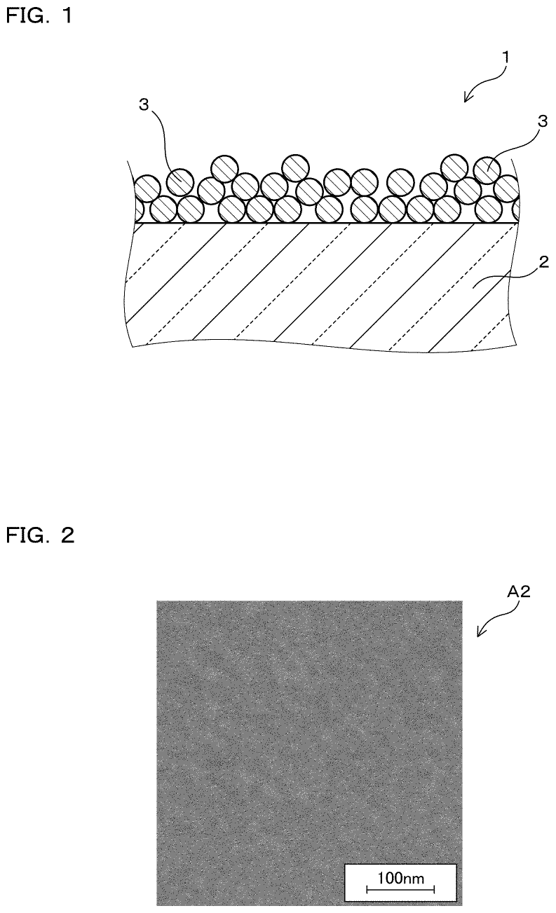

Working examples of the above-mentioned antimicrobial sheet and the manufacturing method thereof will now be explained, with reference to FIG. 1. It is noted that the specific aspects of the antimicrobial sheet and the manufacturing method thereof according to the present invention are not limited to the aspects below, and the structural elements can be modified where appropriate within a range that does not depart from the gist of the present invention.

As shown in FIG. 1, an antimicrobial sheet 1 of the present example comprises a resin film 2 and copper particles 3, which are adhered to one surface of the resin film 2. The antimicrobial sheet 1 can be prepared by, for example, the following method.

First, a transparent film, which contains polyethylene terephthalate and has a thickness of 30 μm, is prepared as the resin film 2. Pure copper is adhered, using a vacuum-depositing method, to one surface of the resin film 2. It is noted that pure copper that is in the form of grains having a diameter of approximately 1 mm and that has a purity of 99.9 mass % or more is used as the evaporation source in the vacuum deposition.

The vacuum deposition can be performed, for example, as follows. First, the resin film is placed on a cooling stage inside the deposition apparatus. Subsequently, the pressure inside the deposition apparatus is reduced. Then, vacuum deposition is performed while the resin film is cooled by the cooling stage. Thus, by performing the vacuum deposition while cooling the resin film, the occurrence of thermal contraction, wrinkles, warpage, or the like of the resin film can be curtailed.

By controlling the pressure inside the apparatus to within the ranges listed in Table 1 and changing the deposition rate and the time where appropriate, the antimicrobial sheets (Test Materials A1-A24) listed in Table 1 could be obtained. It is noted that the deposition rate in the present example was within the range of 0.05-5 nm/s.

The methods of measuring the average circle-equivalent diameter of the copper particles, the adhered amount, and the number of the exposed copper particles on the surface for each of the test materials were as follows.

Average Circle-Equivalent Diameter

An SEM image of the surface to which the copper particles were adhered was acquired for each test material using a field-emission-type, scanning-electron microscope (“SU8230” made by Hitachi High Technologies Corporation). It is noted that the acceleration voltage during SEM image acquisition was set to 1.0 kV, the working distance was set to 3.0 mm, and the observation magnification was set to 100,000 times. From among the copper particles appearing in the obtained SEM image, 30 copper particles for which the entire particle appeared were randomly selected. Furthermore, the arithmetic average of the circle-equivalent diameters of these copper particles were taken as the average circle-equivalent diameter of the copper particles. The average circle-equivalent diameter of the copper particles for each test material was as listed in Table 1.

Number of Exposed Copper Particles on Surface

Within the above-described SEM image, a square-shaped area that was 200 nm on one side was randomly set, and the number of copper particles present within the area was counted. This number was converted to the number per 1 μm² and taken as the number of exposed copper particles on the surface. The number of exposed copper particles on the surface for each test material was as listed in Table 1.

Adhered Amount

The adhered amount of copper was measured by performing X-ray fluorescence analysis, using an X-ray fluorescence analysis apparatus (“RIX3100” made by Rigaku Corporation), on the surface of each test material to which the copper particles were adhered. The adhered amount of copper particles for each test material was as listed in Table 1.

In addition, the methods of evaluating the visible-light transparency and the antimicrobial effects for each test material was as follows.

Visible-Light Transparency

The total light transmittance of each test material was measured at wavelengths of 380-780 nm using a haze meter (“NDH-2000” made by Nippon Denshoku Industries Co., Ltd.) and using a method that conforms to JIS K7361-1:1997. The total light transmittance of each test material was as listed in the “Transmittance” column in Table 1.

In addition, in the present example, the above-described transmittance and the visibility of printed content were evaluated when a printed matter, which was monochromatically printed using a laser printer, and the test material were overlaid. It is noted that, in the printed matter P used in the present example, the alphabetic characters “ABC” were printed in black on a paper surface having a white background, as shown in FIG. 6 to FIG. 9. In the state in which the printed matter and the test material were overlaid, the symbol “A” was recorded in the “Printed Matter Visibility” column in Table 1 in the situation in which the printed content was visible, and symbol “B” was recorded in the situation in which the printed content was not visible.

Antimicrobial Effects

An antimicrobial-processed test piece that exhibited a square shape that was 40 mm on one side was sampled from each test material. In addition, an unprocessed test piece that exhibited a square shape that was 40 mm on one side was sampled from the resin film 2 prior to performing the vacuum deposition. An antimicrobial-properties test was performed on these test pieces using the method stipulated in JIS Z2801:2010. The microbes used in the test were Staphylococcus aureus and Escherichia coli, and the culturing time was set to 24 h.

An antimicrobial-activity value, which indicates the magnitude of the antimicrobial effects, could be calculated, for each test piece, based on the number of living cells after culturing for 24 h. An antimicrobial-activity value R is specifically a value that was calculated by the equation below. It is noted that symbol Ut in the equation below is the average value of the common logarithm of the number of living cells after culturing for 24 h on the unprocessed test piece, and At is the average value of the common logarithm of the number of living cells after culturing for 24 h on the antimicrobial-processed test piece.

R=Ut−At

The antimicrobial-activity value for each test material is listed in Table 1. In the evaluation of antimicrobial effects, the situation in which the antimicrobial-activity value R was 2.0 or more for both Staphylococcus aureus and Escherichia coli was determined to be acceptable, and the situation in which at least one was less than 2.0 was determined to be unacceptable.

TABLE 1

| | | | Average | Number | | Total | | | |
|---|---|---|---|---|---|---|---|---|---|
| | | | Circle- | of | | Light | | | |
| Test | Pressure | | Equivalent | Copper | Adhered | Trans- | | Antimicrobial-Activity Value R | |
| Specimen | Inside | Adherence | Diameter | Particles | Amount | mittance | | Staphylococcus | Escherichia |
| Symbol | Apparatus | Mode | (nm) | (per μm²) | (mg/m²) | (%) | Visibility | aureus | coli |
| A1 | 10⁻⁵ − 10⁻³ Pa | Continuous | — | — | 85 | 28 | A | 3.6 | 0.8 |
| A2 | | film | — | — | 130 | 18 | B | 4.3 | 6.2 |
| A3 | | | — | — | 178 | 17 | B | 4.3 | 6.2 |
| A4 | 10⁻⁴ − 10⁻³ Pa | Particles | 14 | 4030 | 88 | 59 | A | 3.6 | 0.7 |
| A5 | | | 14 | 4184 | 108 | 50 | A | 4.3 | 6.2 |
| A6 | | | 13 | 4710 | 145 | 41 | A | 4.3 | 6.2 |
| A7 | | | 14 | 4210 | 175 | 25 | A | 4.3 | 6.2 |
| A8 | | | 16 | 3842 | 220 | 17 | B | 4.3 | 6.2 |
| A9 | 10⁻³ Pa | Particles | 18 | 3166 | 90 | 53 | A | 4.3 | 0.9 |
| A10 | | | 18 | 3010 | 105 | 42 | A | 4.3 | 6.2 |
| A11 | | | 17 | 3181 | 142 | 32 | A | 4.3 | 6.2 |
| A12 | | | 17 | 3218 | 178 | 22 | A | 4.3 | 6.2 |
| A13 | | | 17 | 3216 | 213 | 16 | B | 4.3 | 6.2 |
| A14 | 10⁻² Pa | Particles | 22 | 2032 | 92 | 50 | A | 4.3 | 0.9 |
| A15 | | | 25 | 1605 | 106 | 38 | A | 4.3 | 6.2 |
| A16 | | | 22 | 2065 | 144 | 29 | A | 4.3 | 6.2 |
| A17 | | | 24 | 1740 | 180 | 20 | A | 4.3 | 6.2 |
| A18 | | | 22 | 1937 | 218 | 14 | B | 4.3 | 6.2 |
| A19 | 1 × 10⁻¹ Pa | Agglomerated | 68 | 199 | 62 | 19 | B | 3.9 | 1 |
| A20 | | particles | 73 | 197 | 100 | 16 | B | 4.3 | 6.2 |
| A21 | | | 69 | 208 | 130 | 15 | B | 4.3 | 6.2 |
| A22 | | | 69 | 206 | 155 | 13 | B | 4.3 | 6.2 |
| A23 | | | 70 | 196 | 200 | 11 | B | 4.3 | 6.2 |
| 24 | 5 × 10⁻¹ Pa | Deposition | — | — | — | — | — | — | — |
| | | not possible | | | | | | | |

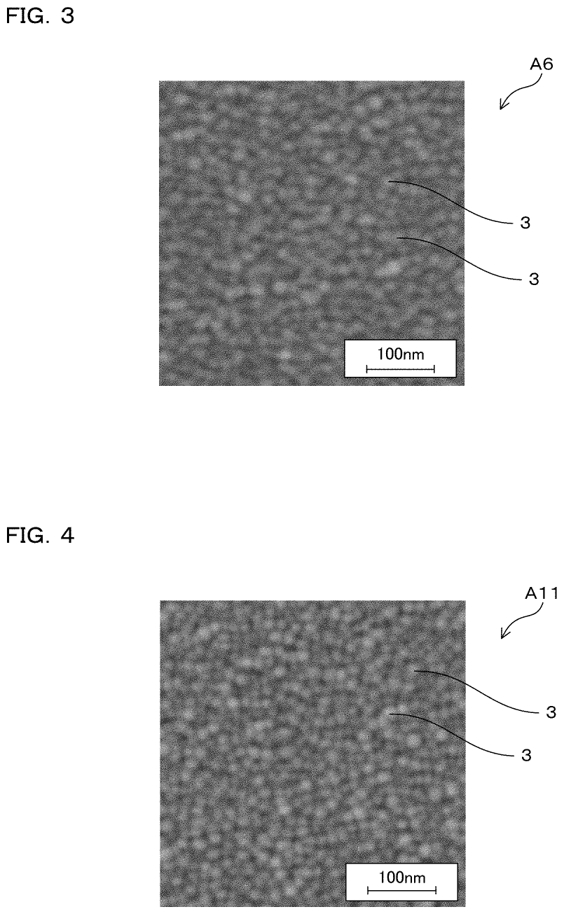

Each of Test Materials A5-A7, A10-A12, A15-A17 comprised copper particles 3, for which the average circle-equivalent diameter was 10-30 nm, on the resin film 2, as shown in FIG. 1. In addition, the adhered amount of the copper particles 3 on each of the test materials was 100-200 mg/m², and the total light transmittance at wavelengths of 380-780 nm was 20% or more. As representative of these test materials, FIG. 3 and FIG. 4 show SEM images of Test Material A6 and Test Material A11, respectively.

As shown in FIG. 3 and FIG. 4, for each of these test materials, the copper particles 3, which were fine, were adhered to the entire surface of the resin film. For this reason, it could be understood that each of the test materials excelled in visible-light transparency and exhibited strong antimicrobial effects, as shown in Table 1.

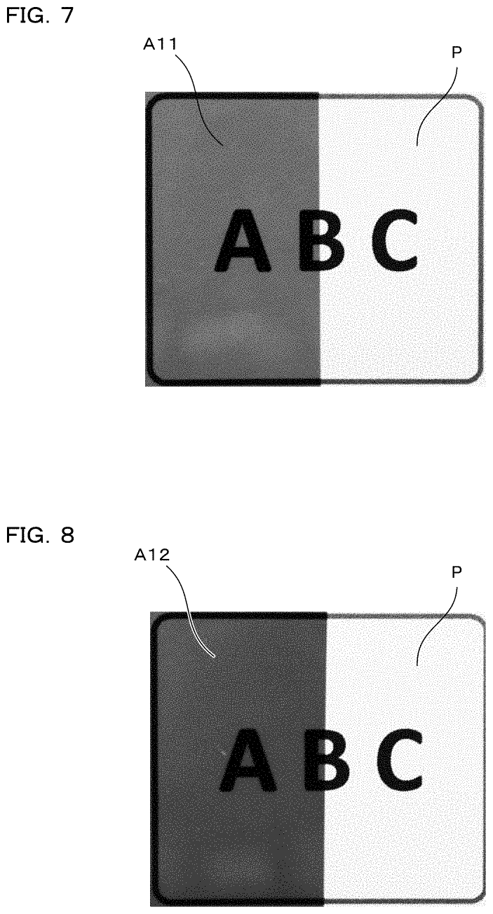

In addition, among these test materials as well, particularly with regard to each of Test Materials A5, A6, A10, A11, and A15, in which the total light transmittance was 30% or more at wavelengths of 380-780 nm, the printed content was easily visible even in the situation in which light from the rear surface was not transmitted when the printed matter P and the test material were overlaid, as in Test Material A10 illustrated in FIG. 6 and Test Material A11 illustrated in FIG. 7. Accordingly, for each of these test materials, antimicrobial effects could be exhibited while ensuring visibility with respect to both an interface, such as a touch panel, that had a backlight, and an interface, such as a keyboard, that did not have a backlight.

In contrast, the test materials for which the total light transmittance was 20% or more and less than 30% at wavelengths of 380-780 nm had low visibility of the printed matter P compared with the test materials for which the total light transmittance was 30% or more, as in Test Material A12 illustrated in FIG. 8. For this reason, in the situation in which the total light transmittance of the antimicrobial sheet is 20% or more and less than 30%, it is preferable to radiate light from the rear of the interface using a backlight or the like in order to improve the visibility of the interface.

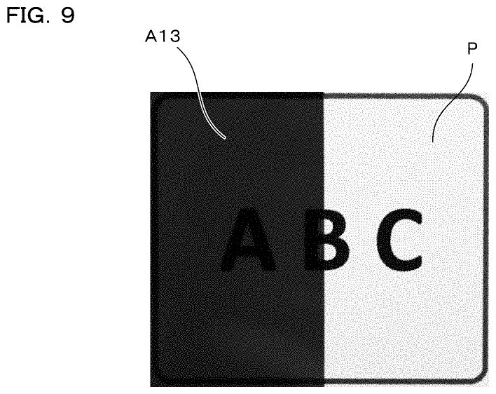

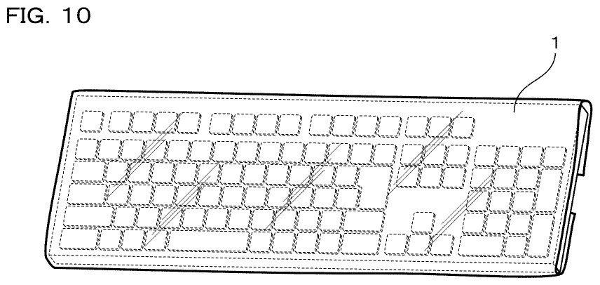

In the situation in which the adhered amount of copper particles 3 was below the above-mentioned range, as shown in Test Materials A4, A9, and A14, there was a risk that the antimicrobial effects would become insufficient. In addition, as shown in Test Materials A8, A13, and A18, even when the average circle-equivalent diameter of the copper particles 3 was within the above-mentioned specific range, the total light transmittance at wavelengths of 380-780 nm was less than 20% in the situation in which the adhered amount was excessive. With regard to these test materials, the printed content of the printed matter P was virtually not visible, as in Test Material A13 illustrated in FIG. 9. Thus, it is not preferable that an antimicrobial sheet, in which the total light transmittance is less than 20% at wavelengths of 380-780 nm, is used for the protection of the interface because it is difficult to view the interface through the antimicrobial sheet.

In addition, when the pressure inside the apparatus fell below the 10⁻⁵ Pa level during the vacuum deposition, a continuous film of pure copper tended to form on the resin film 2, as in Test Material A2 illustrated in FIG. 2. The visible-light transparency of a continuous film of pure copper was lower than layers composed of the copper particles. For this reason, if an attempt was made to make the adhered amount small in order to increase the visible-light transparency, then it led to a decrease in the antimicrobial effects, as in Test Material A1. In addition, if an attempt was made to increase the adhered amount in order to sufficiently obtain the antimicrobial effects, then the total light transmittance at wavelengths of 380-780 nm became less than 20%, as in Test Materials A2, A3.

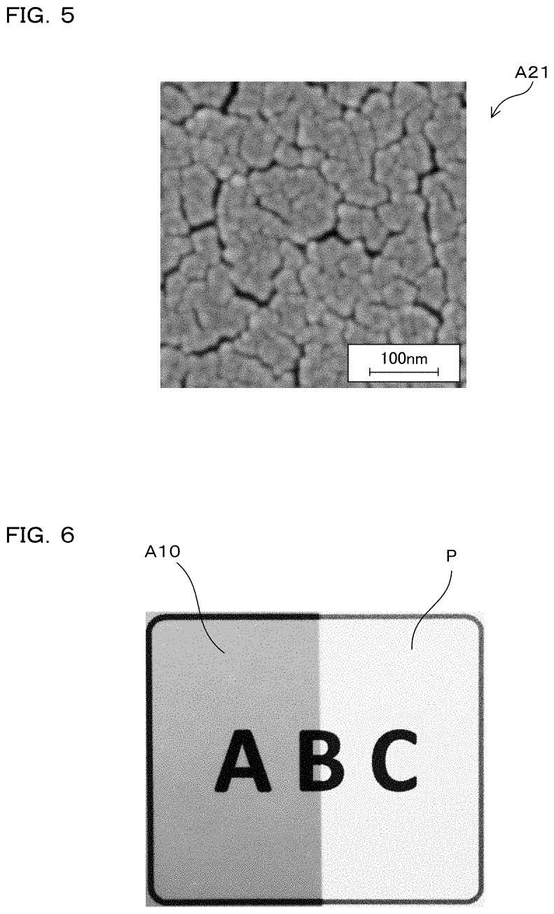

In addition, if the pressure inside the apparatus during the vacuum deposition rose to the 10⁻¹ Pa level, then a structure the same as the continuous film, in which the copper particles agglomerated, tended to form on the resin film 2 as in Test Material A21 illustrated in FIG. 5. In this situation as well, the visible-light transparency was lower than layers composed of copper particles having an average circle-equivalent diameter in the above-mentioned specific range. Consequently, the same as in the case of the continuous film, if an attempt was made to make the adhered amount small in order to increase the visible-light transparency, it led to a decrease in the antimicrobial effects, as in Test Material A19. In addition, if an attempt was made to increase the adhered amount in order to sufficiently obtain the antimicrobial effects, then the total light transmittance at wavelengths of 380-780 nm became less than 20%, as in Test Materials A20-A23.

1. An antimicrobial sheet comprising:
a resin film; and
copper particles adhered to at least one surface of the resin film;
wherein:
the antimicrobial sheet has a total light transmittance at wavelengths of 380-780 nm of 20% or more;
an average circle-equivalent diameter of the copper particles is 10-30 nm; and
100-200 mg/m² of the copper particles are adhered to the resin film.

2. The antimicrobial sheet according to claim 1, wherein the resin film contains one or two or more resins selected from the group consisting of polyester, polyolefin, polycarbonate, polyurethane, polyvinyl chloride, and silicone.

3. The antimicrobial sheet according to claim 1, wherein the resin film has a thickness of 5-250 μm.

4. A keyboard cover comprising the antimicrobial sheet according to claim 1.

5. A method of manufacturing the antimicrobial sheet according to claim 1, comprising:
forming the copper particles on the resin film by performing vacuum deposition such that the pressure is controlled to within a range of 1×10⁻⁴-1×10⁻² Pa.

6. The method according to claim 5, wherein the resin film contains one or two or more resins selected from the group consisting of polyester, polyolefin, polycarbonate, polyurethane, polyvinyl chloride, and silicone.

7. The method according to claim 6, wherein the resin film has a thickness of 5-250 μm.

8. The method according to claim 7, wherein the copper particles are composed of copper having a purity of 99.9 mass % or higher or a copper alloy having a copper content of at least 60 mass %.

9. The method according to claim 8, wherein the number of exposed copper particles on the surface of the antimicrobial sheet is 1,500-5,000 particles/μm².

10. The method according to claim 9, wherein the total light transmittance at wavelengths of 380-780 nm is 40% or more.

11. The method according to claim 10, wherein the pressure during the vacuum deposition is controlled to within the range of 1×10⁻³-1×10⁻² Pa.

12. The method according to claim 11, wherein the vacuum deposition is performed at a deposition rate of 0.5-5 nm/s.

13. The method according to claim 12, wherein the antimicrobial sheet is formed in the shape of a keyboard cover.

14. The antimicrobial sheet according to claim 2, wherein the resin film has a thickness of 5-250 μm.

15. The antimicrobial sheet according to claim 14, wherein the copper particles are composed of copper having a purity of 99.9 mass % or higher or a copper alloy having a copper content of at least 60 mass %.

16. The antimicrobial sheet according to claim 15, wherein the number of exposed copper particles on the surface of the antimicrobial sheet is 1,500-5,000 particles/μm².

17. The antimicrobial sheet according to claim 16, wherein the total light transmittance at wavelengths of 380-780 nm is 40% or more.

18. The antimicrobial sheet according to claim 17, wherein the the resin film contains polyethylene terephthalate.

19. The antimicrobial sheet according to claim 18, wherein the antimicrobial sheet is formed in the shape of a keyboard cover.

20. An antimicrobial sheet comprising:
a polymer sheet having a thickness of 5-250 μm; and
100-200 mg/m² of copper particles disposed on a surface of polymer sheet such that 1,500-5,000 copper particles/μm² are exposed on the surface;
wherein:
the copper particles have a copper content of at least 60 mass % and an average circle-equivalent diameter in the range of 10-30 nm; and
the antimicrobial sheet has a total light transmittance in a wavelength range of 380-780 nm of 20% or more.
